(19) United States
(12) Patent Application Publication
(10) Pub. No.: US 2003/0127424 A1
(43) Pub. Date: Jul. 10, 2003

(54) Method of fabricating magnetic recording heads using asymmetric focused-Ion-beam trimming

(75) Inventors: Thomas William Clinton, Pittsburgh, PA (US); Giora J. Tarnopolsky, Palo Alto, CA (US); Zhenyong Z. Zhang, Milpitas, CA (US); Petrus Antonius van der Heijden, Cranberry Township, PA (US)

Correspondence Address: Robert P. Lenart, Pietragallo, Bosick & Gordon, One Oxford Centre, 38th Floor, 301 Grant Street, Pittsburgh, PA, 15219, US

(73) Assignee: Seagate Technology LLC, Scotts Valley, CA

(21) Appl. No.: 10/243,044

(22) Filed: Sep. 13, 2002

Related U.S. Application Data
(60) Provisional application No. 60/346,607, filed on Jan. 8, 2002.

(51) Int. Cl. H01L 21/306

(52) U.S. Cl. 216/22; 156/345.4

(57) ABSTRACT

A method of fabricating a magnetic structure, the method including: forming a first magnetic structure having a first side and a second side, and using a focused ion beam to etch only one of the first and second sides, to reduce a width of the magnetic structure. The first magnetic structure can be formed using a full-field lithographic technique such as optical lithography. The magnetic structure can include a rectangular portion with the first and second sides being opposite sides of the rectangular portion. The focused ion beam can comprise a gallium ion beam. Magnetic recording heads having a magnetic structure fabricated according to the method are also included.

### CROSS REFERENCE TO RELATED APPLICATION

This application claims the benefit of U.S. Provisional Patent Application Serial No. 60/346,607, filed Jan. 8, 2002.

### FIELD OF THE INVENTION

This invention relates to methods for fabricating magnetic recording heads, and more particularly to the use of focused ion beam trimming, and magnetic recording heads fabricated using focused ion beam trimming.

### BACKGROUND OF THE INVENTION

Focused-Ion-Beam (FIB) instruments are widely used in research, development and manufacturing in high-tech industries, such as semiconductor and magnetic storage, as diagnostic, characterization, lithography and fabrication tools. Commercial FIB equipment can produce beam width diameters down to less than 10 nm, for use in microscopy, material removal (sputtering), lithography, and ion exposure (dosing) with this same spatial resolution. One industry, in particular, where FIB instruments are rapidly being implemented is the magnetic disc storage industry. Critical features in recording heads are rapidly approaching 100 nm and smaller, necessitating lithographic techniques at the manufacturing level capable of defining such line widths. FIB trimming of write poles in magnetic recording heads has been developed and is being advanced as a manufacturing process for defining critical features of the heads. In particular, FIB manufacturers provide FIB trimming instruments designed specifically to trim write poles as part of a head manufacturing process. However, there are known degrading effects to magnetic recording properties and magnetic materials, in general, due to milling with and exposure to the gallium (Ga⁺) ion beams used in commercial FIB instruments.

A critical issue for any manufacturing process is throughput, and this is a significant issue with a serial process such as FIB-based lithography. Initially, multiple devices are formed on a wafer and every device must be trimmed individually. The overall throughput is dictated by the stage-movement time to go from device to device on the wafer, as well as the processing time per device. Therefore, there is the potential for substantial improvement in overall throughput if the trimming process-time (beam-on time) per device is reduced significantly. This necessitates minimizing the time it takes to trim a write pole.

There is a need for a FIB process that increases magnetic recording head fabrication throughput, decreases pole-width and write-width standard deviation, and decreases ion-beam exposure and the consequent degrading effects on the pole material.

### SUMMARY OF THE INVENTION

This invention provides a method of fabricating a magnetic structure, the method including: forming a first magnetic structure having a first side and a second side, and using a focused ion beam to etch only one of the first and second sides, to reduce a width of the magnetic structure. The first magnetic structure can be formed using a full-field exposure technique such as optical lithography. The magnetic structure can include a rectangular portion with the first and second sides being opposite sides of the rectangular portion. The focused ion beam can comprise a gallium ion beam.

The magnetic structure can comprise a pole structure in a magnetic recording head. A second magnetic pole structure having a first end can be spaced from a first end of the first magnetic pole structure to form a gap between the first magnetic pole structure and the second magnetic pole structure, and the focused ion beam can be used to etch only one side of the second magnetic pole structure. The first magnetic pole structure can form a write pole of a magnetic recording head and the second magnetic pole structure can form a return pole of a magnetic recording head. Magnetic recording heads having a magnetic structure fabricated according to the method are also included.

The invention also encompasses magnetic recording heads comprising a pole piece having first and second sides, wherein the first side is defined by a full-field lithographic technique and the second side is defined by a focused ion beam technique.

In another aspect, the invention further includes an apparatus for fabricating a magnetic structure, the apparatus comprising means for forming a first magnetic structure having a first side and a second side, and means for using a focused ion beam to etch only one of the first side and the second side, to reduce a width of the magnetic structure.

### BRIEF DESCRIPTION OF THE DRAWINGS

FIG. 1 is a plan view of an intermediate structure formed on a portion of a wafer during the manufacture of a magnetic write head.

FIG. 2 is a plan view of the intermediate structure of FIG. 1 showing a prior technique of focused ion beam etching.

FIG. 3 is a plan view of the intermediate structure of FIG. 1 that has been subjected to focused ion beam etching using the technique illustrated in FIG. 2.

FIG. 4 is an air bearing surface view of the intermediate structure of FIG. 1.

FIG. 5 is an air bearing surface view of the intermediate structure of FIG. 3.

FIG. 6 is a schematic representation of a portion of the pole pieces of the intermediate structure of FIG. 5 that has been subject to focused ion beam etching.

FIG. 7 is a plan view of an intermediate structure formed on a portion of a wafer during the manufacture of a magnetic write head.

FIG. 8 is a plan view of the intermediate structure of FIG. 7 showing the technique of focused ion beam etching of this invention.

FIG. 9 is a plan view of the intermediate structure of FIG. 7 that has been subjected to focused ion beam etching in accordance with the invention.

FIG. 10 is an air bearing surface view of the intermediate structure of FIG. 7.

FIG. 11 is an air bearing surface view of the intermediate structure of FIG. 9 that has been subjected to focused ion beam etching of this invention.

FIG. 12 is a schematic representation of a portion of the pole pieces of the intermediate structure of FIG. 11 that has been subject to focused ion beam etching.

FIG. 13 is an air bearing surface view of another intermediate structure formed during the manufacture of a magnetic write head.

FIG. 14 is an air bearing surface view of the intermediate structure of FIG. 13 showing a prior technique of focused ion beam etching.

FIG. 15 is an air bearing surface view of the intermediate structure of FIG. 14 that has been subjected to focused ion beam etching.

FIG. 16 is an air bearing surface view of an intermediate structure formed during the manufacture of a magnetic write head.

FIG. 17 is an air bearing surface view of the intermediate structure of FIG. 16 showing the technique of focused ion beam etching of this invention.

FIG. 18 is an air bearing surface view of the intermediate structure of FIG. 17 that has been subjected to focused ion beam etching in accordance with the invention.

FIG. 19 is a table of properties of several magnetic heads constructed using symmetric and asymmetric FIB processing.

FIG. 20 is a graph of the read head signal amplitude versus crosstrack position produced by two longitudinal writers.

FIG. 21 is a graph of the read head signal amplitude versus crosstrack position produced by two perpendicular writers.

### DETAILED DESCRIPTION OF THE INVENTION

The conventional FIB process for defining a pole width in a magnetic recording head is to FIB trim a lithographically defined write pole on each side of the pole. That process uses a symmetric trim technique, to achieve the targeted pole width. The method of this invention provides an asymmetric trimming process whereby only one side of a write pole is FIB trimmed to achieve the target width. This invention can be implemented in a head manufacturing process that utilizes a FIB trimming instrument for write pole definition. The method can also be used in FIB lithography for read-head and semiconductor chip or device fabrication.

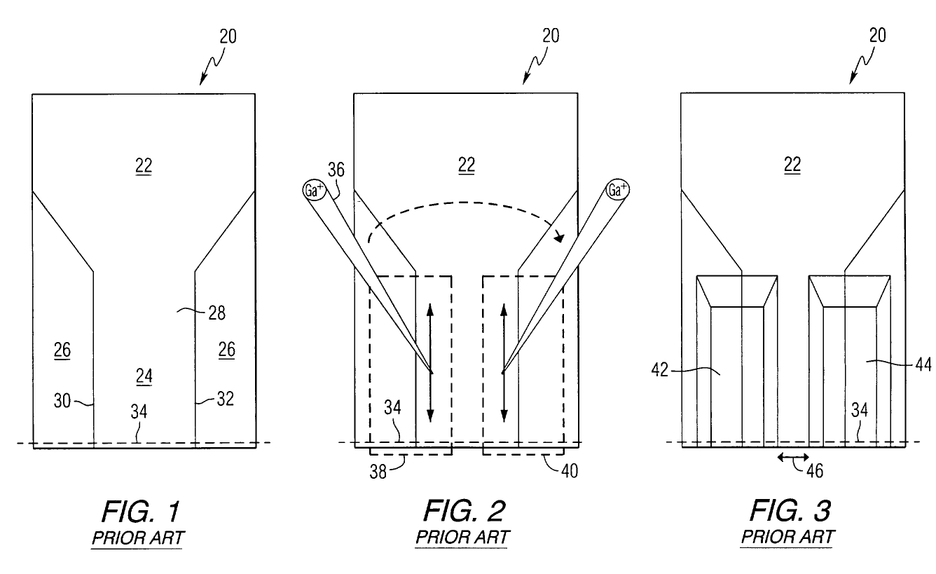

Intermediate structures that can be formed in the fabrication of magnetic write heads are depicted in FIGS. 1, 2 and 3. A plurality of these structures would be formed on a wafer. FIG. 1 is a plan view of an intermediate structure 20 formed on a wafer during the manufacture of a magnetic write head. The structure includes a back yoke 22, a top pole 24 and an insulator 26. The top pole has a generally rectangular portion 28, having first and second sides 30 and 32. A lap line 34 indicates the position of an air bearing surface of a magnetic recording head that will be fabricated using the structure of FIG. 1. FIG. 2 is a plan view of the intermediate structure 20 of FIG. 1 showing a prior technique of focused ion beam etching. A focused ion beam 36 is scanned over the areas illustrated by blocks 38 and 40, sputtering away material as the beam is rastered over the areas. This process removes material from both of the first and second sides of the rectangular portion of the top pole, to form a top pole having a desired width. FIG. 3 is a wafer level view of the intermediate structure of FIG. 1 after it has been subject to focused ion beam etching. In this view, troughs 42 and 44 are shown on opposite sides of the top pole to define a pole width 46.

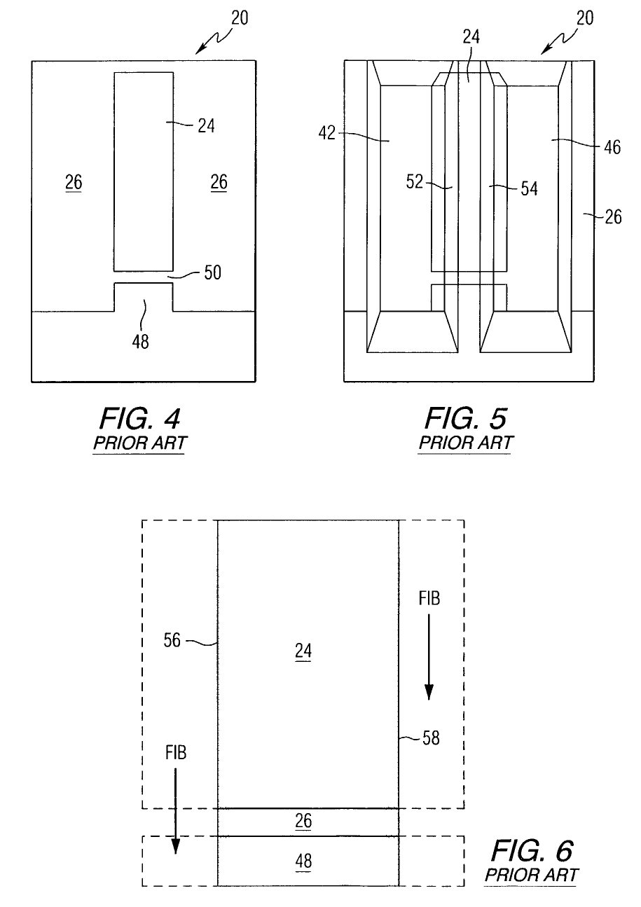

FIG. 4 is an air bearing surface (ABS) view of the intermediate structure 20 of FIG. 1 as it would appear when the structure has been cut along lap line 34 prior to FIB pole trimming. In this view, the structure is shown to include the top pole 24 and a bottom pole 48 separated by a gap 50 that is filled by the insulator 26. The insulator 26 is also positioned on each side of the top pole. FIG. 5 is an air bearing surface view of the intermediate structure of FIG. 3 that has been subjected to symmetric focused ion beam etching. In FIG. 5 troughs 42 and 44 are shown to extend vertically along opposite sides 52 and 54 of the top pole 24.

FIG. 6 is a schematic representation of a portion of the intermediate structure of FIG. 5 that has been subject to focused ion beam etching. The top pole 24 in FIG. 6 is seen to have sections, illustrated by shaded portions 56 and 58, where Ga⁺ ions have been implanted into the pole material. Implanted gallium ions can have a detrimental effect on the magnetic properties of the pole material. As the desired width of pole pieces continues to get smaller, the sections of implanted pole material will represent a larger portion of the total pole cross-sectional area and thereby have a greater effect on the magnetic performance of the pole.

As illustrated in FIGS. 1-6, in a conventional FIB process, the write-pole widths are initially defined on the wafer using a full-field lithographic technique such as optical lithography, for example, at a critical dimension (CD) greater than 100 nm, where the critical dimension describes a dimension dictated by specifications for the device operation, or the process to fabricate the device. For example, the critical dimension can be a desired pole width at an air bearing surface of a magnetic write head. Then, a serial process of FIB trimming each head on the wafer is employed, whereby the ion beam removes (trims) material from the sides of a lithographically defined write pole until the targeted width is achieved, with CD capability of 100 nm, or better. The remaining pole material has been directly exposed to the Ga⁺ beam at the edges, and there is a lateral penetration depth of several tens of nanometers that effectively poisons the magnetic material as depicted in FIG. 6. It is presumably this region of the FIB defined write pole that can result in degraded recording performance such as reduced overwrite capability and a difference between the physical pole width and the magnetic width. In addition, from a lithography standpoint, this effectively limits the line edge roughness (LER) of the write pole to the Ga⁺ implantation spatial profile. While the precise mechanism for the degradation of the magnetic properties is not known, it is clear that the negative effects increase with increased exposure to the ion beam.

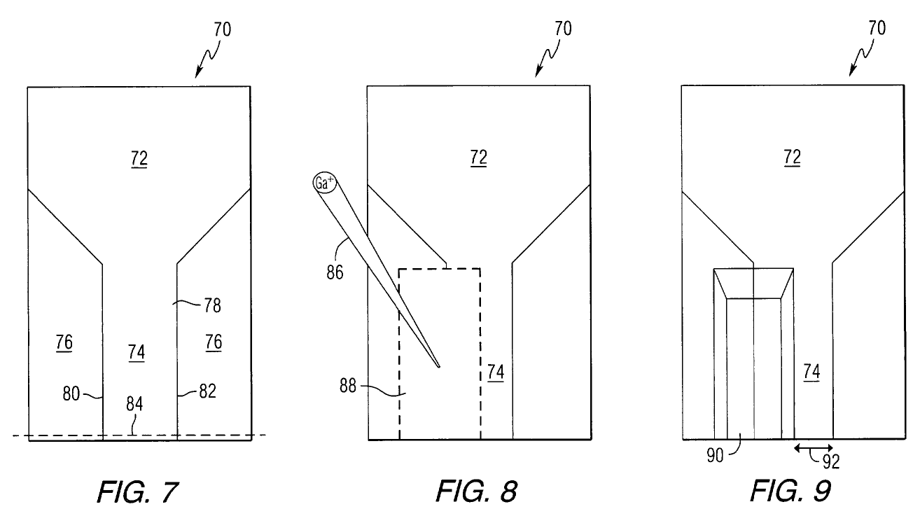

This makes it desirable to develop FIB processing techniques that minimize the exposure of the magnetic material to the beam, thus minimizing the total Ga⁺ dose it takes. FIGS. 7, 8 and 9 illustrate the invention using a FIB to trim only one side of a lithographically pre-defined write pole. This process is referred to herein as an asymmetric trim. FIG. 7 is a plan view of an intermediate structure 70 formed during the manufacture of a magnetic write head. The structure includes a back yoke 72, a top pole 74 and an insulator 76. The top pole includes a generally rectangular portion 78 having first and second sides 80 and 82. A lap line 84 indicates the position of an air bearing surface of a magnetic recording head that will be fabricated using the structure of FIG. 7. The intermediate structure of FIG. 7 can be formed using a full-field lithographic technique, such as optical lithography. FIG. 8 is a plan view of the intermediate structure of FIG. 7 showing the technique of asymmetric focused ion beam etching of this invention. A focused ion beam 86 is rastered over an area 88 to sputter away material from one side of the rectangular portion of the top pole. FIG. 9 is a plan view of the intermediate structure of FIG. 7 after it has been subject to focused ion beam etching. In this view, a trough 90 is shown on one side of the top pole to define a pole width 92.

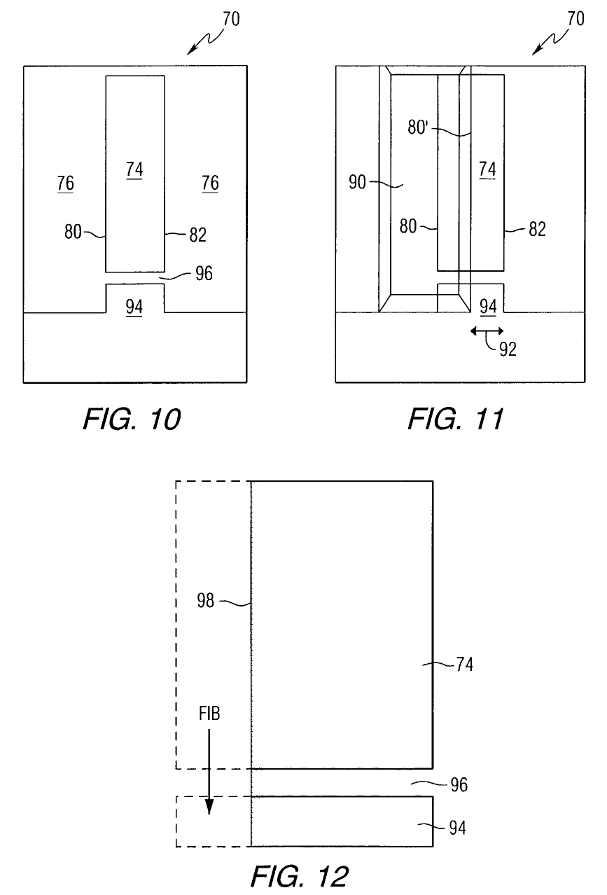

FIG. 10 is an air bearing surface view of the intermediate structure 70 of FIG. 7, formed during the manufacture of a magnetic write head as it would appear if cut along the lap line 84. The intermediate structure is seen to include the top pole 74 and a bottom pole 94 separated by a gap 96. The insulator 76 is positioned on each side of the top pole. FIG. 11 is an air bearing surface view of the intermediate structure of FIG. 9 that has been subjected to asymmetric focused ion beam etching in accordance with this invention. In FIG. 11 a trough 90 is shown to extend vertically along a first one 80 of the sides of the top pole.

This yields a write pole, for example, with one edge 80′ defined by the FIB and one edge 82 defined by a full-field lithographic technique, but with the critical dimension capability of a FIB as discussed above. The asymmetric process can be implemented with a straightforward variation of a symmetric FIB trimming process. One side of the lithographically pre-defined pole does not get FIBed and serves as a reference for aligning the FIB pattern to define the other edge of the pole. End point detection is a common feature on a commercial FIB, and can be implemented readily in a wafer-level manufacturing process to control the milling depth to achieve good alignment with the unFIBed side of the pole, as indicated in FIG. 11. The ion beam patterning is half that of the symmetric process, cutting exposure time in half and significantly improving throughput.

FIG. 12 is a schematic representation of a portion of the intermediate structure of FIG. 11, depicting the Ga⁺ ion implantation profile 98 at the ABS of an asymmetrically trimmed writer. The asymmetric trim reduces the Ga⁺ dose to the magnetic material of the pole by a factor of two as compared to the prior processes of symmetric focused ion beam etching. This significantly decreases the degradation to the magnetic properties and the recording performance of the write head. The line edge roughness (LER) of the edges of the pole piece is not compromised by the asymmetric trim, and is likely improved over a symmetric trim, since LER for full-field lithographic techniques should be as good or better than that of a FIB defined edge. Additionally, since an ion beam pattern is aligned on only one side to define the pole width, the pole-width (which translates to the write width) standard deviation is reduced by as much as a factor of \sqrt{2} from a symmetric trim requiring two such alignments. By reducing the portion of the write pole that is subject to embedded ions, the write width will be closer to the physical pole width, and recording performance will be improved as compared to conventional FIB defined write heads.

FIB trimmed recording heads at the head gimbal assembly (HGA) level using both symmetric and asymmetric trimming processes have been fabricated and the recording performance of the heads characterized on a spin stand. Though HGA-level trimming may not be appropriate for manufacturing, the processes developed are readily transferable to wafer-level FIB processing for manufacturing.

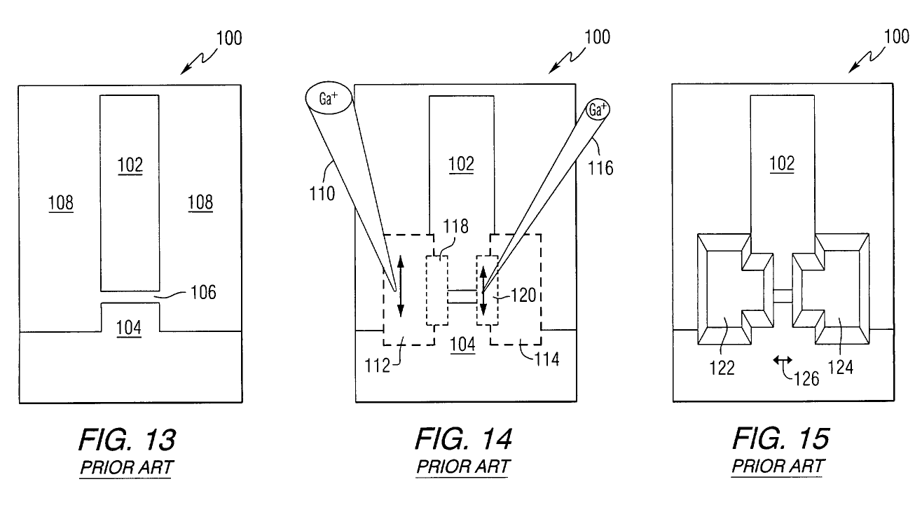

FIGS. 13, 14 and 15 illustrate the HGA-level symmetric trimming process used in these experiments. FIG. 13 is an air bearing surface view of another intermediate structure 100 formed during the manufacture of a magnetic write head. The intermediate structure 100 is seen to include the top pole 102 and a bottom pole 104 separated by a gap 106. The insulator 108 is positioned on each side of the top pole and in the gap. FIG. 14 is an air bearing surface view of the intermediate structure of FIG. 13 showing a symmetrical technique of focused ion beam etching. First a bulk ion beam 110 was used to mill the areas defined by rectangles 112 and 114. Then a polish ion beam 116 was used to mill the areas defined by rectangles 118 and 120 to a specified depth at the air-bearing surface (ABS). The milled areas were determined by the need to avoid re-deposition of sputtered material. The milling depth impacts the ion-beam exposure of the write-pole edge, but this is common to both symmetric and asymmetric trimming. The longitudinal head was trimmed to a narrower width than the as-fabricated width. The as-fabricated widths ranged from 350 nm to 250 nm, and were trimmed down to widths as narrow as about 100 nm. FIG. 15 is an air bearing surface view of the intermediate structure of FIG. 14 that has been subject to focused ion beam etching. Troughs 122 and 124 are shown on opposite sides of the pole. The troughs define the width 126 of the pole.

In one example of a head made using the symmetric trimming process, the trimmed width was measured to be about 190 nm reduced from an as-fabricated width of 330 nm. Numerous heads have been fabricated using this process with two primary variables, one being the trimmed width, and two being the milling depth.

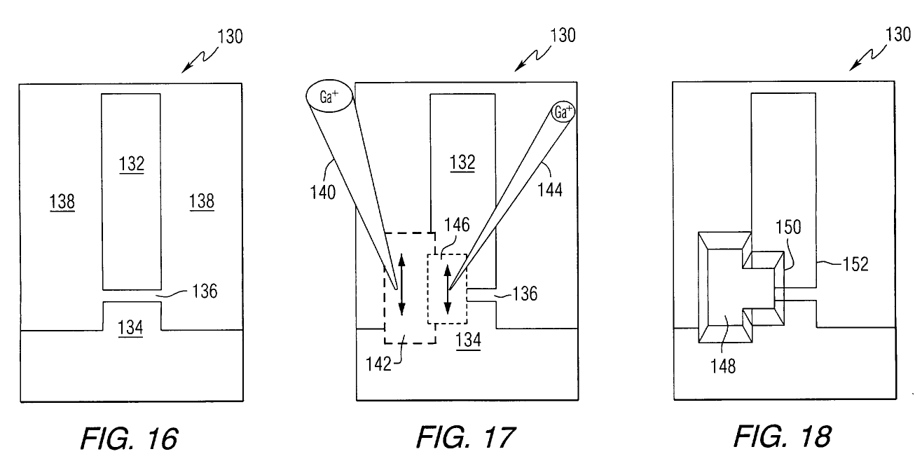

Next, we fabricated numerous longitudinal heads using the asymmetric trimming process as shown schematically in FIGS. 16, 17 and 18. FIG. 16 is an air bearing surface view of an intermediate structure 130 formed during the manufacture of a magnetic write head. The intermediate structure 130 is seen to include the top pole 132 and a bottom pole 134 separated by a gap 136. The insulator 138 is positioned on each side of the top pole and in the gap. FIG. 17 is an air bearing surface view of the intermediate structure of FIG. 16 showing an asymmetrical technique of focused ion beam etching. First a bulk ion beam 140 was used to mill the area defined by rectangle 142. Then a polish ion beam 144 was used to mill the area defined by rectangle 146 to a specified depth at the air-bearing surface (ABS). FIG. 18 is an air bearing surface view of the intermediate structure of FIG. 17 that has been subject to focused ion beam etching in accordance with the invention. Trough 148 defines one side 150 of the pole and the other side 152 of the pole is defined by the optical lithography process used to make the intermediate structure of FIG. 16.

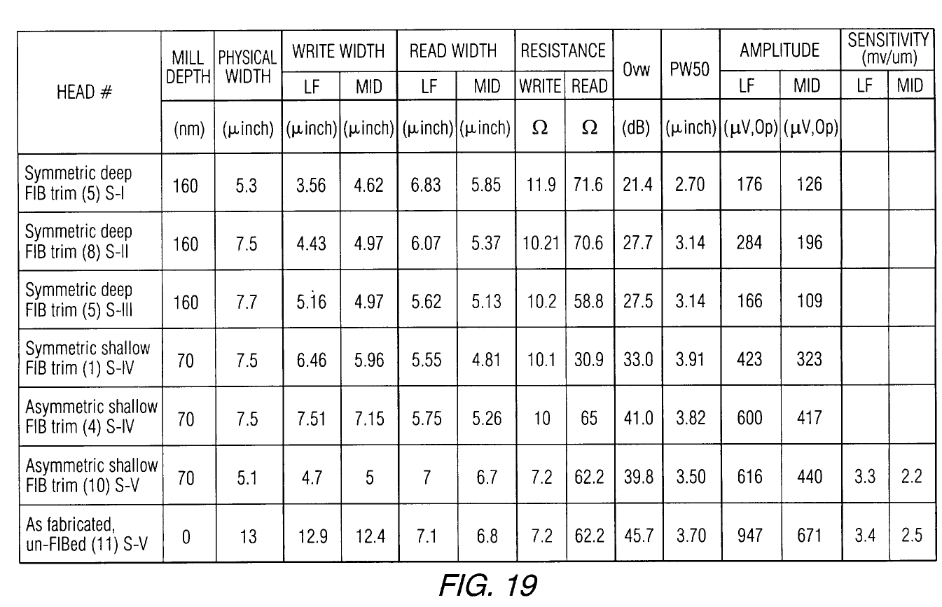

The various heads were characterized on a spin-stand and key performance parameters are tabulated in FIG. 19, where each row of data is an average over all the heads that were processed in the same way, with number of heads averaged given in parenthesis in column 1. The larger the mill depth the greater the exposure of the pole edges to the Ga⁺ beam, and the greater potential for degradation to the magnetic pole material and, thus, the writing performance. This is born out in the data of FIG. 19, as the results for symmetric-trim head series I-III with 160 nm mill depths reveal large gaps between physical pole width and the write width, as well as poor overwrite capability of less than 30 dB. The series IV data are for a symmetrically trimmed head using the same process as series I-III but with a 70 nm mill depth, and correspondingly smaller Ga⁺ dose. These results show a closer agreement between the physical and written widths as well as a better overwrite capability. The series IV asymmetrically trimmed heads show even better results with essentially complete agreement between physical and written widths, and the overwrite has jumped to 41 dB at this larger write width. The improvement in overwrite, thus far, cannot be explained conclusively as being the result of the reduced Ga⁺ exposure, because shallower mill depths and increased write widths will result in a lower reluctance to magnetic flux flow in the writer, which could also result in better overwrite. However, the results from the series V heads are conclusive in this matter. The asymmetrically trimmed series V heads, also milled to a 70 nm depth, have considerably better overwrite capability at even narrower write widths than the series IV symmetric heads, demonstrating the asymmetric method improves recording performance and write width definition independently. The table of FIG. 19 also has results for the series V heads before FIB trimming, where the sensitivity and the difference between physical and written widths are essentially the same before and after asymmetric FIB processing. Thus, the data demonstrate the negative effects of Ga⁺ exposure to write head characteristics but, more importantly, the data reveal how the present invention asymmetric trimming process eradicates the negative effects, especially as compared to a symmetric FIB trim.

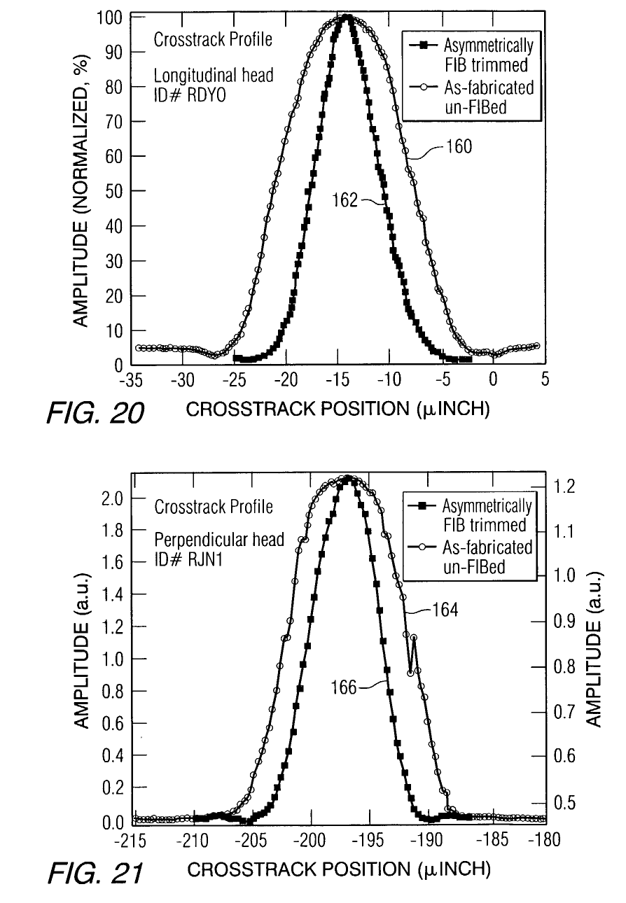

Furthermore, an asymmetrically FIB trimmed writer does not produce any observable asymmetry in a written track. The data of FIG. 20 represent crosstrack profiles taken on a head before (line 160) and after asymmetric FIB trimming (line 162). To obtain the data of FIG. 20, the writer before FIBing was as-fabricated using a symmetric optical-lithography process. A magnetic track was written to longitudinal media and then the track was scanned in the cross track direction by the read sensor of the merged head, scanning both track edges. In the case of the asymmetrically trimmed writer, the sensor crossed the track edges associated with a FIB-defined pole edge and the as-fabricated pole edge. Since the disc was spinning, the sensor scanned the track over its downtrack length, and, thus, the data are the average (track average amplitude) over this length of the written track. The data exhibit no asymmetry associated with the asymmetric FIBing process, as the crosstrack profiles before and after FIBing are symmetric. The different widths are the direct result of the pole trimming and the consequently narrower written track. Thus, we conclude there is no measurable asymmetry in the recording performance resulting from an asymmetric trimming process as compared to a longitudinal writer having pole width defined symmetrically.

Similar experiments have been conducted on perpendicular recording heads, where the pole width was asymmetrically FIB trimmed at the HGA level with a process similar to that described above for the longitudinal heads and depicted in FIG. 16, 17 and 18. The trimming of perpendicular heads involved additional FIB steps beyond that of the longitudinal heads, but these steps are common to both a symmetric and an asymmetric trimming process, and, thus, will not be described here. The data of FIG. 21 are, again, crosstrack profiles taken on a head before (line 164) and after asymmetric FIB trimming (line 166). The writer before asymmetric trimming had an as-fabricated pole width defined by a symmetric optical-lithography process. A magnetic track was written to perpendicular media and then the track was scanned in the cross track direction by the read sensor of the merged head, scanning both track edges. In the case of the asymmetrically trimmed writer, the sensor crossed the track edges associated with a FIB-defined pole edge and the as-fabricated pole edge. The data exhibited no asymmetry associated with the asymmetric FIBing process, as the crosstrack profiles before and after FIBing were symmetric. The different widths are the direct result of the pole trimming and the consequently narrower written track. Thus, we conclude there is no measurable asymmetry in the recording performance resulting from an asymmetric trimming process as compared to a writer having pole width defined symmetrically.

The asymmetric trimming method can be implemented in place of many FIB-lithography applications that use a symmetric FIB process, with similar benefits as outlined herein. For example, FIB-based lithography can be used to define magneto-resistive (MR) read-head critical dimensions, and the asymmetric process would have many of the same advantages over a symmetric process because there are similar issues regarding FIB exposure to MR materials, as well as the same throughput needs and limitations in reader processing. Other applications would be in semiconductor chip or device fabrication where FIB processing is employed, and where there are similar issues regarding Ga⁺ exposure and throughput limitations.

In the particular application of write-head manufacturing, the asymmetric FIB trimming method increases fabrication throughput, decreases pole-width and write-width standard deviation, decreases ion-beam exposure and the consequent degrading effects in the pole material, effectively reduces line edge roughness, reduces the margin between physical pole width and write width, and recording performance, such as overwrite capability, is improved as compared to conventional FIB defined write heads. The method of this invention can be readily implemented in a head manufacturing process that utilizes a FIB-trimming instrument for write pole definition.

While the invention has been described in terms of several examples, it will be apparent to those skilled in the art that various changes and modifications can be made to the disclosed examples without departing from the invention as defined by the following claims.

What is claimed is:

1. A method of fabricating a magnetic structure, the method comprising:
forming a first magnetic structure having a first side and a second side; and
using a focused ion beam to etch only one of the first side and the second side, to reduce a width of the magnetic structure.

2. The method of claim 1, wherein the step of forming a first magnetic structure having a first and second sides comprises:
using a full-field lithographic technique to form the first magnetic structure.

3. The method of claim 2, wherein the full-field lithographic technique comprises:
optical lithography.

4. The method of claim 1, wherein the magnetic structure includes a rectangular portion and the first and second sides are opposite sides of the rectangular portion.

5. The method of claim 1, wherein the magnetic structure comprises:
a pole structure in a magnetic recording head.

6. The method of claim 5, further comprising:
forming a second magnetic pole structure having a first end spaced from a first end of the first magnetic pole structure to form a gap between the first magnetic pole structure and the second magnetic pole structure; and
using the focused ion beam to etch only one side of the second magnetic pole structure.

7. The method of claim 6, wherein the first magnetic pole structure forms a write pole of a magnetic recording head and the second magnetic pole structure forms a return pole of a magnetic recording head.

8. The method of claim 5, further comprising:
using a full-field lithographic technique to form a plurality of additional magnetic pole structures, each having a first side and a second side; and
using the focused ion beam to etch only one of the first and second sides of each of the additional magnetic pole structures.

9. The method of claim 8, wherein the full-field lithographic technique comprises:
optical lithography.

10. The method of claim 8, wherein the first magnetic pole structure and the additional magnetic pole structures are formed on a wafer.

11. The method of claim 1, wherein the first side and the second side are opposite sides of a rectangular portion of the first magnetic structure.

12. The method of claim 1, wherein the magnetic structure comprises:
a pole piece of a magnetic recording head.

13. The method of claim 1, wherein the focused ion beam comprises a gallium ion beam.

14. A magnetic recording head having a magnetic structure fabricated according to the method of claim 1.

15. A magnetic recording head comprising:
a pole piece having first and second sides, wherein the first side is defined by a full-field lithographic technique and the second side is defined by a focused ion beam technique.

16. An apparatus for fabricating a magnetic structure, the apparatus comprising:
means for forming a first magnetic structure having a first side and a second side; and
means for using a focused ion beam to etch only one of the first side and the second side, to reduce a width of the magnetic structure.
